(19) United States
(12) Patent Application Publication
(10) Pub. No.: US 2005/0017350 A1
(43) Pub. Date: Jan. 27, 2005

(54) Thermal enhanced extended surface tape for integrated circuit heat dissipation

(75) Inventors: William D. Corti, New Windsor, NY (US); David C. Long, Wappingers Falls, NY (US); Joseph O. Marsh, Poughkeepsie, NY (US); Francis X. Scanzano, Newburgh, NY (US); Michael Won, Highland, NY (US); Tsorng-Dih Yuan, Hopewell Junction, NY (US)

Correspondence Address: DELIO & PETERSON, LLC, 121 WHITNEY AVENUE, NEW HAVEN, CT, 06510, US

(73) Assignee: International Business Machines Corporation, Armonk, NY (US)

(21) Appl. No.: 10/921,752

(22) Filed: Aug. 18, 2004

Related U.S. Application Data
(63) Continuation of application No. 09/876,508, filed on Jun. 7, 2001.

(51) Int. Cl. H01L 23/10

(52) U.S. Cl. 257/706

(57) ABSTRACT

A thermal conductive tape article is provided which is adhered to the surface of an integrated circuit device to dissipate heat from the device. The thermal conductive tape article is preferably corrugated and may have a number of configurations providing an expanded surface area. The corrugated tape article may also have a metal strip bonded to one or both sides of the tape article to form a single-faced or double-faced corrugated tape article. The tape article is preferably made of copper or aluminum.

### BACKGROUND OF THE INVENTION

1. Field of the Invention

This invention relates to dissipating heat from electronic components and, more particularly, to a thermal conductive tape having an extended surface area which is applied to the surface of an integrated circuit for heat dissipation.

2. Description of Related Art

As the need for power (heat) dissipation of electronic components such as integrated circuits (IC) and particularly lower power applications of less than 10 watts continues to increase, it is of great commercial interest to enhance packaging thermal characteristics. Existing methods are generally expensive and require improvement in addressing the unit cost issues. For convenience, the following description will be directed to semiconductors (IC's), however, it will be appreciated by those skilled in the art that the invention can be used for any type electronic component.

Traditional methods to enhance packaging thermal characteristics include using heat spreaders or heat sinks on the integrated circuit component or on the package surface. Such methods are expensive and the mechanical properties required at the interface between the heat spreader and the package or IC surface such as adhesion are very important and much material development time and resources are spent on this thereby increasing the cost of the IC device.

Traditional heat dissipation methods as shown in FIGS. 7A and 7B use heat spreaders and/or heat sinks which are usually made of thick pieces of aluminum or copper.

Packages with an embedded heat sink or heat slug are other options. Other options are a cavity down plastic ball grid array with a copper heat spreader or Power PQ2 plastic quad flat pack with an embedded heat slug. These options typically are expensive and such a cost increase in the package becomes prohibitive.

For example, standard plastic packages such as plastic quad flat pack (PQFP) or plastic ball grid array (PBGA) are limited in power dissipation to between 1-3 watt for a unit 23 mm square in size. This has limited its acceptance for packaging consideration in many application opportunities such as portable computers and hand held communications devices. In order to address the increasing power requirements, more expensive packages are needed which reduces the cost performance competitiveness of the package.

Bearing in mind the problems and deficiencies of the prior art, it is therefore an object of the present invention to provide a method to enhance electronic component heat dissipation, especially integrated circuit electronic components.

It is another object of the present invention to provide a thermal conductive article which is applied to electronic components such as integrated circuits for the dissipation of heat from the component.

A further object of the invention is to provide a method to enhance heat dissipation for electronic components including integrated circuit devices wherein a thermally conductive article is formed and continuously applied to the surface of the electronic component.

Still other objects and advantages will in part be obvious; and will in part be apparent from the specification.

### SUMMARY OF THE INVENTION

The above and other objects and advantages, which will be apparent to one of skill in the art, are achieved in the present invention which is directed to, in a first aspect, a method to enhance integrated circuit device heat dissipation comprising the steps of:
providing an integrated circuit device having a surface;
providing a flexible strip of thermal conductive material preferably corrugated (expanded surface area) and preferably having a thermal conductive adhesive on at least one side thereof; and
adhering the strip to the surface of the integrated circuit device.

In another aspect of the invention the strip of thermal conductive material is a metal such as copper or aluminum having a thickness of about 0.0005 inch to 0.00 inch (0.5 mil to 10 mil), which has preferably been corrugated to provide an expanded surface area up to 500% more or above the surface area of the original strip.

In a further aspect of the invention any form of corrugation may be formed in the thermal conductive material strip to increase the surface area of the strip and preferred corrugation includes a repeating series of triangles, a repeating series of convex and concave portions comprising opposed vertical sidewall portions, and connecting horizontal top and bottom portions, a repeating series of convex portions comprising angled sidewalls and a connecting horizontal top portion and a connecting triangular concave portion, a repeating series of vertical fins and a repeating series of loops.

In yet another aspect of the invention the flexible thermal conductor material strip may be adhered to the integrated circuit to be cooled by employing adhesive on the strip.

A preferred corrugated flexible strip has a thermal conductive material flat strip bonded (connected) to one side of the corrugated strip forming a single-faced flexible corrugated strip. Another embodiment employs two flat flexible strips of thermal conductive material each bonded to each side of the flexible corrugated strip forming a double-faced flexible corrugated strip. In both the single-faced and double-faced flexible corrugated strips, an adhesive is used to adhere the strip to the integrated circuit device and the adhesive is preferably on the flat flexible strip.

In yet another aspect of the invention the adhesive used is thermally conductive to enhance the heat dissipation properties of the corrugated tape article.

Another aspect of the invention is directed to a method to enhance integrated circuit device heat dissipation comprising the steps of:
providing an integrated circuit device having a surface;
providing a strip of flexible flat thermal conductive material;
forming corrugations in the flexible thermal conductive material if desired; and
adhering the flat or corrugated flexible thermal conductive material to the surface of the integrated circuit.

In another aspect of the invention the flexible thermal conductive material which has been corrugated may be fed from the corrugation step directly to the surface of the integrated circuit to provide a continuous system for making the corrugated tape and applying the corrugated tape to the integrated circuit in a sequential series of operations.

In yet another aspect of the invention, after forming the corrugations in a flexible strip of thermal conductive material, either one or more flat strips of thermal conductive material may be bonded to one or both sides of the corrugated material to form a single-face or double-face thermal conductive material corrugated tape article for application to the surface of the integrated circuit device.

In another aspect of the invention an article of manufacture is provided for dissipating heat for integrated circuit and other electronic component devices comprising a flexible flat or preferred corrugated strip of thermal conductive material preferably having an adhesive thereon which adhesive contacts and adheres the strip to the surface of the integrated circuit device. Other articles of manufacture embodiments include a single-faced or a double-faced corrugated thermal conductive material tape preferably with an adhesive thereon. A preferred article of the invention provides a thin coating on the surface of the strip such as a varnish, paint, anodized layer, oxide layer, etc. to increase the heat emissivity of the article.

### BRIEF DESCRIPTION OF THE DRAWINGS

The features of the invention believed to be novel and the elements characteristic of the invention are set forth with particularity in the appended claims. The figures are for illustration purposes only and are not drawn to scale. The invention itself, however, both as to organization and method of operation, may best be understood by reference to the detailed description which follows taken in conjunction with the accompanying drawings in which:

FIGS. 1A, 1B and 1C show different tape articles of the invention applied to the surface of an integrated circuit chip for cooling the chip.

FIGS. 2A, 2B, 2C, 2D and 2E show different corrugated tape articles of the invention.

FIGS. 3A, 3B, 3C, 3D and 3E show other corrugated tape articles of the invention.

FIGS. 4A, 4B, 4C, 4D and 4E show additional corrugated tape articles of the invention.

FIG. 5 shows an electronic component having within the component housing a chip containing electronic component assembly cooled using a tape article of the invention.

FIG. 6A shows a method and apparatus for forming corrugations in a flat metal tape to form a corrugated tape article of the invention which is used to cool integrated circuit devices.

FIG. 6B shows another method and apparatus of the invention for forming a corrugated metal tape article from a flat tape which, after forming, is applied directly to the surface of an integrated circuit device.

FIGS. 7A and 7B show prior art methods of dissipating heat on integrated circuit devices.

### DESCRIPTION OF THE PREFERRED EMBODIMENT(S)

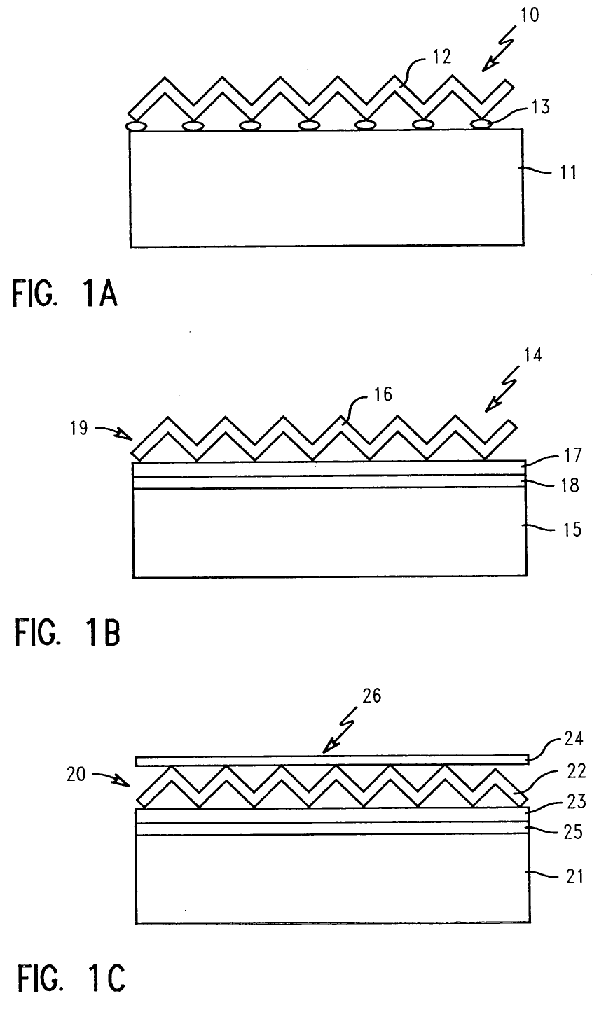

In describing the preferred embodiment of the present invention, reference will be made herein to FIGS. 1A-7B of the drawings in which like numerals refer to like features of the invention. Features of the invention are not necessarily shown to scale in the drawings.

Broadly stated, this invention comprises using a thermally conductive flexible material preferably with an extended surface area which is applied to the surface of an electronic component to thermally enhance heat dissipation from the electronic component such as IC devices.

The preferred heat dissipation article of the invention comprises two components. One component is a flexible thermal conductive material strip such as copper, aluminum, gold, silver, phosphor, bronze, beryllium copper and other metal or thermal conductive materials which has been preferably corrugated. The other component is an adhesive material which can be either a pressure sensitive or other kind known in the art. By using a label process, the flexible layer of copper, aluminum, or other high thermal conductivity material strip can be coated with an adhesive or pressure sensitive material to form the heat dissipation article of the invention. The strip may also be used without an adhesive thereon but an adhesive would be needed to adhere the strip to the IC device.

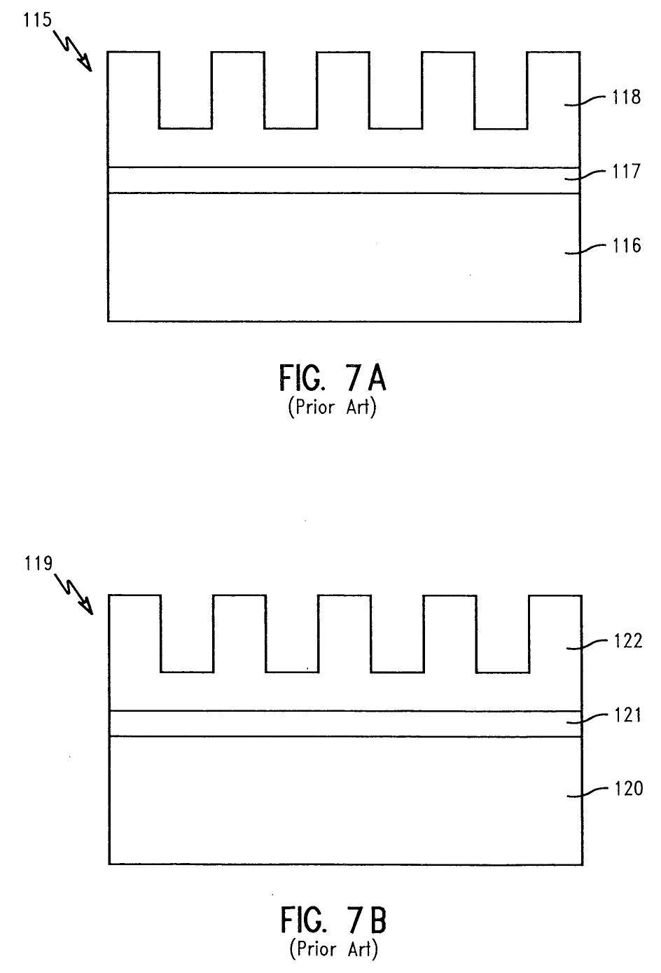

The flexible thermal conductive material is much thinner and lower mass than the traditional inflexible heat spreader and heat sink structures of the prior art as shown in FIGS. 7A and 7B and is a very small mass relative to the IC device or other material surface to which it is applied. This offers a significant mechanical and conformal compliance with the IC device during thermal cycling of the IC device and the IC devices survive shock and vibration tests as compared to the traditional heat spreader and heat sink devices which may more easily become separated from the IC device because of adhesive failure.

Tables 1 and 2 below illustrate and compare the thermal performance of a flat, non-corrugated tape article of this invention. Table 1 and 2 show the thermal benefit using a metal tape as compared with standard package in PQFP and PBGA, respectively. Thus, using a tape and increasing the thickness of the tape decreases the thermal resistance R and increases the heat dissipation of the device to which the tape is attached.

TABLE 1

| Heatsink | | % Heat Dissipation |
|---|---|---|
| Thickness | R_ja C/w | Improvement |
| No Heatsink | 16.9 | 0 |
| 10 micron | 16 | 5 |
| 30 micron | 15.8 | 7 |
| 40 micron | 14.9 | 13 |
| 50 micron | 14.6 | 16 |

TABLE 2

| Heatsink | | % Heat Dissipation |
|---|---|---|
| Thickness | R_ja C/w | Improvement |
| No Heatsink | 49.7 | 0 |
| 10 micron | 37.6 | 23 |
| 30 micron | 32.8 | 50 |
| 40 micron | 31.1 | 60 |
| 50 micron | 29.3 | 70 |

Table 3 shows the data for PQFP implementation with air flow across the device. The use of a tape label lowers the thermal resistance R of the device to which the tape is applied.

TABLE 3

| | | % Heat Dissipation |
|---|---|---|
| | R_ja C/w | Improvement |
| Low air No Heatsink | 64 | 0 |
| Low air flow Heatsink | 42 | 52 |
| Forced air No Heatsink | 53 | 0 |
| Forced air Heatsink | 35.7 | 48 |

Table 4 shows the thermal performance of a tape article of the invention based on varying the tape thickness.

TABLE 4

| | | % Heat Dissipation |
|---|---|---|
| Heatsink Thickness | R_ja C/w | Improvement |
| No Heatsink | 47 | 0 |
| 10 micron Heatsink | 41 | 13 |
| 20 micron Heatsink | 39.5 | 16 |
| 30 micron Heatsink | 38 | 19 |
| 40 micron Heatsink | 37 | 21 |
| 50 micron Heatsink | 36.2 | 22 |
| 75 micron Heatsink | 35 | 25.5 |
| 100 micron Heatsink | 34 | 27.5 |
| 200 micron Heatsink | 32.8 | 30 |
| 300 micron Heatsink | 31.5 | 33 |

The improved heat dissipation properties for an enhanced surface area tape of the invention are presented in Table 5. The results show that the enhanced surface area label tape article of the invention has higher heat transfer properties than increasing the thickness of a flat tape and is preferred for most applications requiring heat dissipation.

TABLE 5

| | | % Heat Dissipation |
|---|---|---|
| | R_ja C/w | Improvement |
| No Heatsink | 47 | 0 |
| 30 micron Heatsink | 38 | 19 |
| 30 micron adding | 31.2 | 34 |
| 250% area | | |
| 30 micron adding | 28 | 40 |
| 360% area | | |
| 30 micron adding | 24 | 49 |
| 500% area | | |

The strip material and adhesive and their dimensions may vary widely. A one mil thick metal strip has been found suitable for most applications but can vary up to about 10 mil or higher. The adhesive is typically 0.5 to 5 mil thick.

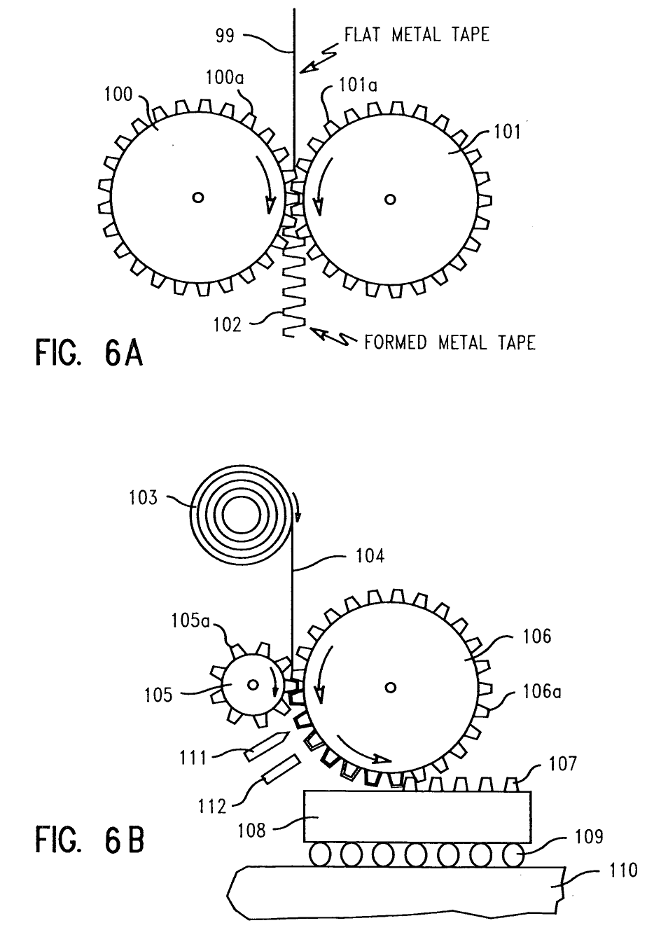

The corrugated article can then be fabricated using methods such as forming the corrugations by feeding the thin metal through turning meshed gears as shown in FIG. 6A and FIG. 6B. Attachment of the body to a heating surface (IC device) can be done by a direct attachment at room temperature.

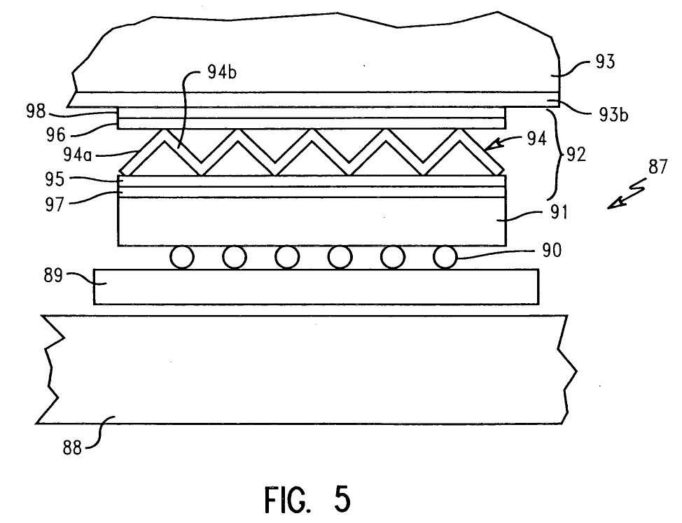

This invention can use all metal materials and adhesive materials and because of the small mass on the metal side, the tape is very light in weight and offers a strong bonding to the surface to which it is attached. As discussed above, previous designs require specially defined adhesive materials due to the large mass involved in the heat spreader or heat sink metal part whereas the tape of the invention requires only a thin metal material strip and many standard adhesives may be used. Additionally the formed metallic tape can be used as a comformable thermal connection from the semiconductor device to the enclosure of the electrical assembly as seen in FIG. 5.

Referring firstly to FIGS. 7A and 7B, these figures show heat dissipation devices of the prior art which are not acceptable for a number of reasons including cost, effectiveness, difficulty of fabrication and operating life.

FIG. 7A shows an electronic component 115 comprising a chip 116 having a heat spreader of 117 on the surface thereof and a heat dissipation device containing fins 118 on top of the heat spreader. As is known in the art, heat spreaders and heat dissipation fin devices are solid structural devices which have considerable weight and are expensive.

Referring to FIG. 7B, another integrated circuit device 119 comprises a chip 120 and a heat dissipation fin device 122 which is adhered to the chip using a thermal paste 121.

The structures 118 and 122 in FIGS. 7A and 7B are typically about 3 to 20 mm thick.

Referring now to FIGS. 1A, 1B and 1C, three different tape articles of the invention having a triangular corrugation are shown attached to chips for cooling the chip. In FIG. 1A, an integrated circuit device shown generally as 10 comprises a chip 11, and a corrugated metal tape article 12 adhered to the chip by adhesive 13 wherein the adhesive is applied to the distal portion of one side of the corrugated metal tape article, and the distal portion is in contact with the chip surface.

In FIG. 1B, another integrated circuit device shown generally as 14 comprises a chip 15 having a corrugated tape article 19 attached to the chip. Corrugated tape article 19 comprises a corrugated metal strip 16 bonded to a flat metal strip 17 which has an adhesive 18 thereon for applying and adhering the tape article 19 to the chip 15. This is an example of a single-face tape article.

In FIG. 1C, a double-faced corrugated tape article 26 is shown adhered to chip 21 forming component assembly 20. The corrugated tape article 26 comprises a corrugated metal strip 22 with flat metal strips 23 and 24 bonded to opposed distal sides of the corrugated metal 22. An adhesive 25 on metal strip 23 is used to adhere the corrugated tape article 26 to chip 21.

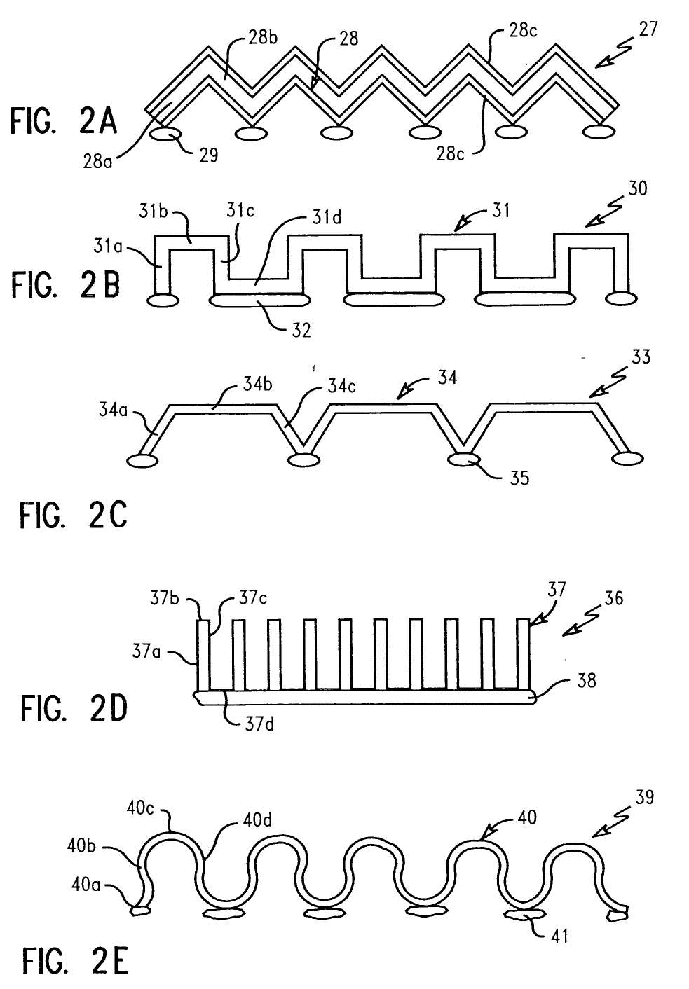

Referring now to FIGS. 2A-2E, a number of different tape article structures of the invention are shown.

In FIG. 2A, tape article 27 comprises a corrugated metal 28 having a triangular shape with repeating opposed angled sidewalls 28a and 28b. Adhesive 29 is applied to the distal end of the corrugated metal 28 for adherence to a chip or other IC device. This embodiment shows a coating 28c on the surface of metal 28 to increase the emissivity of the device. The coating 28c may be an oxide, varnish, paint, etc. and is typically about 0.05 mil to 1 mil thick.

FIG. 2B shows tape article 30 comprising a repeating series of convex and concave portions comprising opposed vertical sidewall portions 31a and 31c, top connecting horizontal portion 31b and connecting bottom horizontal portion 31d. An adhesive 32 is applied to the lower part of bottom portion 31d for adherence to a chip or other IC device.

FIG. 2C shows a corrugated tape article 33 comprising a repeating series of convex portions comprising angled opposed sidewalls 34a and 34c, a top connecting horizontal portion 34b and connecting concave triangular portions. An adhesive 35 is applied at the base of the concave triangular portions for adherence of the tape article to a chip or other IC device.

FIG. 2D shows a fin type corrugated tape article 36 comprising a corrugated metal 37 having a repeating series of vertical opposed sidewalls 37a and 37c, a top connecting portion 37b and a bottom connecting portion 37d. An adhesive 38 is applied to the lower part of bottom portion 37b for adherence of the tape article 36 to a chip or IC device.

FIG. 2E shows a loop type corrugated tape 39. The loop of material 40 comprises opposed sidewalls 40b and 40d and a connecting upper portion 40c and a connecting lower portion 40a. An adhesive 41 is applied to the lower portion of bottom portion 40a for adherence to an integrated circuit device.

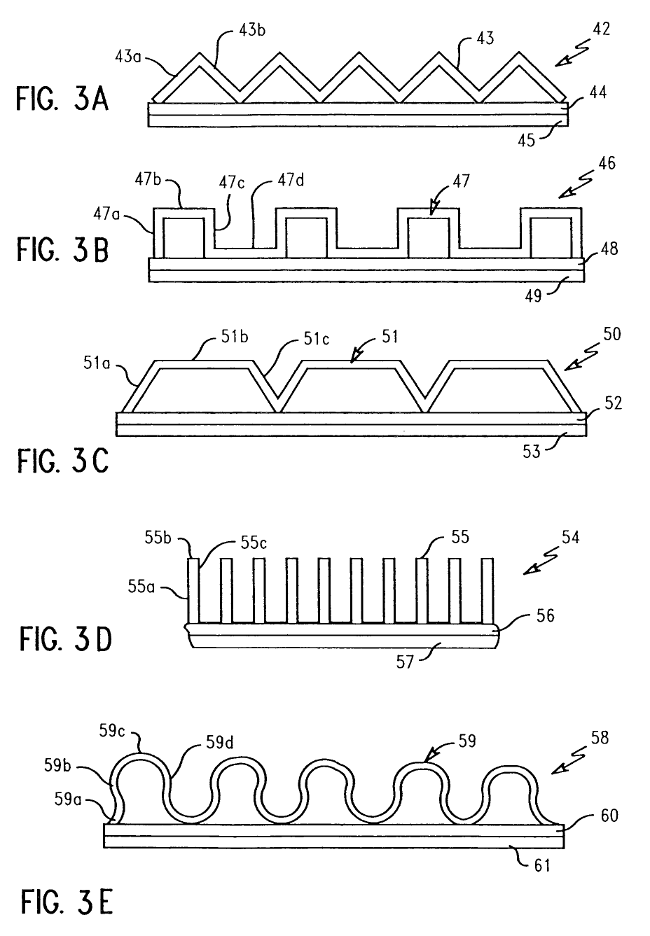

FIGS. 3A-3E parallel FIG. 2A-2E with the difference being the use of a flat metal strip along the one distal side of the corrugated metal forming a single-faced corrugated article sheet. Thus, in FIG. 3A, a triangular corrugated metal tape article 42 is shown as triangular metal strip 43 with a flat metal strip 44 bonded at the lower juncture of triangular sidewalls 43a and 43b. An adhesive 45 is applied to the bottom of flat metal strip adhesive 44 for adherence to an integrated circuit device.

FIG. 3B shows a tape article 46 comprising a repeating series of convex and concave portions 47 having vertical opposed sidewalls 47a and 47c, a connecting top horizontal portion 47b and a connecting lower horizontal portion 47d. A flat metal strip 48 is bonded to the lower part of lower portion 47d and an adhesive 49 is applied thereto for adherence to an integrated circuit device.

FIG. 3C shows a corrugated single-faced tape article 50 comprising a corrugated metal 51 comprising a repeating series of convex portions having angled opposed sidewalls 51a and 51c and a connecting top horizontal portion 51b. A flat metal strip 52 is bonded at the juncture of the angled sidewalls and an adhesive 53 is applied to the lower portion of metal tape 52.

FIG. 3D shows a corrugated tape article 54 of the invention comprising a repeating series of vertical fins 55 having vertical opposed sidewalls 55a and 55c, an upper connecting portion 55b and a lower connecting portion 55d. A flat metal strip 56 is bonded to the corrugated metal at the lower portion of 55d and an adhesive 57 is applied to the metal strip.

In FIG. 3E, a corrugated tape article 58 is shown comprising a series of loops 59 which loops have opposed sidewalls 59b and 59d, a connecting upper portion 59c and a connecting lower portion 59a. A thin flat metal strip 60 is bonded to the bottom of the lower portion 59a and an adhesive 61 is applied to the bottom of the metal strip 60.

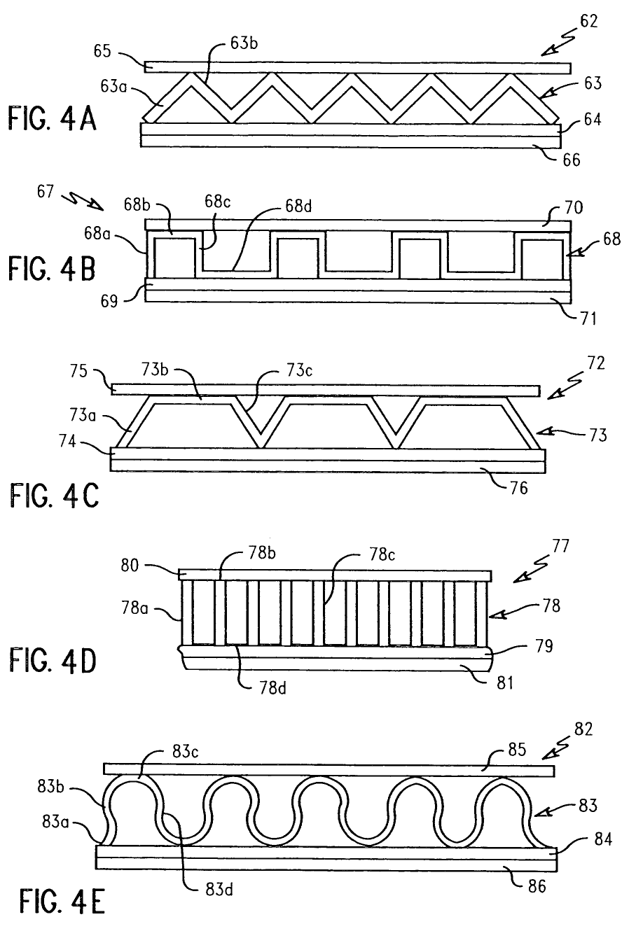

FIGS. 4A-4E parallel FIGS. 2A-2E and 3A-3E and show double-faced tape articles of the invention.

In FIG. 4A a tape article shown as 62 comprises a corrugated triangular portion 63 having angled opposed sidewalls 63a and 63b. A flat metal strip 64 and a second flat metal strip 65 are bonded at opposite sides of the corrugated metal portion 63 and an adhesive 66 is applied to the bottom of strip 64 for adherence to an integrated circuit device.

In FIG. 4B, a tape article shown as 67 comprises a corrugated metal portion 68 comprising a repeating series of convex and concave portions comprising opposed vertical sidewalls portions 68a and 68c, a top connecting horizontal portion 68b and a lower connecting horizontal portion 68d. A flat metal strip 69 is bonded to the lower portion 68d and a second flat metal strip is bonded to the upper portion 68b forming a double-faced tape. An adhesive 71 is shown applied to the bottom of metal strip 69 for adherence to an integrated circuit device.

Referring to FIG. 4C, a corrugated tape article 72 is shown having a corrugated metal portion 73 comprising a repeating series of convex portions comprising angled opposed sidewalls 73a and 73c and a connecting horizontal top portion 73b. A flat metal strip 74 is bonded to corrugated metal structure 73 at the juncture of the angled sidewalls and another flat metal strip 75 is bonded to the top portion 73b. A double-faced tape article is thus formed and an adhesive 76 is applied to the bottom of tape 74 for adherence to an integrated circuit device.

In FIG. 4D, a tape article 77 is shown having a corrugated metal portion 78 comprising a repeating series of vertical fins comprising vertical opposed sidewalls 78a and 78c, a connecting top portion 78b and a connecting lower portion 78d. A flat metal strip 79 is bonded to the corrugated metal portion 78 at the lower portion 78d and another metal strip 80 is bonded to the structure at the top portion 78b. An adhesive 81 is applied to the bottom of metal strip 79 for adherence to an integrated circuit device.

FIG. 4E shows a loop double-faced tape article 82 comprising a loop metal corrugated structure 83 comprising opposed sidewalls 83a and 83c, an upper portion 83b and a lower portion 83d. A flat metal strip 84 is bonded to lower portion 83d and a different flat metal strip 85 bonded to upper portion 83b. An adhesive 86 is applied to the lower portion of strip 84 for adherence to an integrated circuit device.

FIG. 5 shows use of a tape article 87 of the invention to dissipate heat in an electronic component such as a portable computer or portable phone, etc. The electronic component has a lower housing 88 and an opposed upper housing 93. A printed circuit board or other electronic device 89 is secured in the component and is attached to chip 91 through solder balls 90. On top of chip 91 is placed a tape article of the invention shown in composite as numeral 92. Tape article 92 comprises a corrugated triangle metal portion 94 having opposed angled flat metal sides 94a and 94b. Adhesive 97 is applied to bonded metal strip 95 and adhesive 98 applied to bonded metal strip 96 to adhere the tape device 92 to chip 91 and upper housing 93, respectively. If upper housing 93 is a metal housing or a plastic housing with a thin metal deposited on its inner surface (shown as 93b) often done for shielding, greater thermal improvement will be achieved.

FIG. 6A shows one method for making a corrugated tape article of the invention. Thus, a flat metal tape 99 is fed between revolving intermeshing gears 100 and 101 having a meshing gear structure 100a and 101a, respectively. Upon passing of the metal tape through the gears, a corrugated metal tape 102 is formed having a structure formed by the meshing gears. This tape corresponds generally to the tape shown in FIG. 2B. Other corrugated tape articles could be formed depending on the shape of the gears.

FIG. 6B shows the sequential continuous steps of forming a corrugated tape article of the invention and applying the corrugated tape article to the surface of an integrated circuit component. Thus, a metal tape spool 103 feeds out a metal strip 104 which passes through gears 105 and 106 having meshing corrugations 105a and 106a. The corrugated tape 107 may be cut using cutter 111 when desired and an adhesive also applied to the tape using applicator 112. Tape article 107 is shown applied to the surface of chip 108 which chip is part of electronic component 110 having a solder ball connection 109 to chip 108.

While the present invention has been particularly described, in conjunction with a specific preferred embodiment, it is evident that many alternatives, modifications and variations will be apparent to those skilled in the art in light of the foregoing description. It is therefore contemplated that the appended claims will embrace any such alternatives, modifications and variations as falling within the true scope and spirit of the present invention.

1. A method to enhance integrated circuit device heat dissipation comprising the steps of:
providing an integrated circuit device having a surface;
providing a flexible corrugated strip of a thermal conductive material having a flat flexible tape strip of a thermal conductive material bonded to each side thereto forming a double-faced flexible corrugated tape strip article; and
adhering the double-faced flexible corrugated tape strip article to the surface of the integrated circuit device.

2. (Canceled)

3. The method of claim 1 wherein both tape strips are metal and copper or aluminum.

4. The method of claim 3 wherein the thickness of both tape strips is 0.5 mil to 10 mil.

5. The method of claim 4 wherein the corrugated strip has corrugations in the shape of a repeating series of triangles.

6. The method of claim 4 wherein the corrugations in the strip are in the shape of a repeating series of convex and concave portions comprising sidewall portions, top portions and bottom portions.

7. The method of claim 4 wherein the corrugations in the strip are in the shape of a repeating series of convex portions comprising angled sidewalls and a top portion and a triangular concave portion.

8. The method of claim 4 wherein the corrugations in the strip are in the shape of a series of vertical fins.

9. The method of claim 4 wherein the corrugating in the strip are in the shape of a repeating series of loops.

10. The method of claim 1 wherein the flat flexible tape strips have an adhesive thereon to adhere the strip to the integrated circuit device.

11.-15. (Canceled)

16. A method to enhance integrated circuit device heat dissipation comprising the steps of:
providing an integrated circuit device having a surface;
providing a tape strip of flexible flat thermal conductive material;
forming corrugations in the tape strip of the flexible thermal conductive material; and
bonding a thermal conductive material flat tape strip to each side of the flexible corrugated tape strip forming a double-faced flexible corrugated tape strip article;
adhering the corrugated flexible thermal conductive material to the surface of an integrated circuit device.

17. The method of claim 16 wherein an adhesive is applied to each side of the thermal conductive material flat tape strip surface.

18.-23. (Canceled)

24. An article of manufacture for dissipating heat for integrated circuit devices comprising a corrugated flexible tape strip of thermal conductive material having a flat flexible tape strip of a thermal conductive material bonded to each side forming a double-faced flexible corrugated tape strip article which will contact with and adhere the article to an integrated circuit device.

25.-28. (Canceled)

29. The article of claim 24 wherein each side of the flat flexible strip of thermal conductive material has an adhesive thereon.

30. The article of claim 24 which has been surface treated to increase the emmisivity of the article.

31. (Canceled)

32. An electronic component assembly comprising a housing containing an electronic component which is cooled by adhering the flexible article of claim 24 to the electronic component and the housing.

33. The electronic component assembly of claim 32 wherein the housing is metal or has a thin metal coating thereon.

34. The electronic component assembly of claim 32 wherein the flexible article used is the article of claim 29.
